(19) United States
(12) Patent Application Publication
(10) Pub. No.: US 2015/0019802 A1
(43) Pub. Date: Jan. 15, 2015

(54) MONOLITHIC THREE DIMENSIONAL (3D) RANDOM ACCESS MEMORY (RAM) ARRAY ARCHITECTURE WITH BITCELL AND LOGIC PARTITIONING

(71) Applicant: QUALCOMM Incorporated, San Diego, CA (US)

(72) Inventors: Pratyush Kamal, San Diego, CA (US); Yang Du, Carlsbad, CA (US)

(73) Assignee: QUALCOMM Incorporated, San Diego, CA (US)

(21) Appl. No.: 14/012,478

(22) Filed: Aug. 28, 2013

Related U.S. Application Data
(60) Provisional application No. 61/845,044, filed on Jul. 11, 2013.

(51) Int. Cl. G11C 7/10

(52) U.S. Cl. CPC G11C 7/1072
USPC 711/105; 711/104

(57) ABSTRACT

A monolithic three dimensional (3D) memory cell array architecture with bitcell and logic partitioning is disclosed. A 3D integrated circuit (IC) (3DIC) is proposed which folds or otherwise stacks elements of the memory cells into different tiers within the 3DIC. Each tier of the 3DIC has memory cells as well as access logic including global block control logic therein. By positioning the access logic and global block control logic in each tier with the memory cells, the length of the bit and word lines for each memory call are shortened, allowing for reduced supply voltages as well as generally reducing the overall footprint of the memory device.

### PRIORITY APPLICATION

The present application claims priority to U.S. Provisional Patent Application Ser. No. 61/845,044 filed on Jul. 11, 2013 and entitled “A MONOLITHIC THREE DIMENSIONAL (3D) STATIC RANDOM ACCESS MEMORY (SRAM) ARRAY ARCHITECTURE WITH BITCELL AND LOGIC PARTITIONING,” which is incorporated herein by reference in its entirety.

### BACKGROUND

I. Field of the Disclosure

The technology of the disclosure relates generally to memory cells for use with computing devices.

II. Background

Mobile communication devices have become common in current society. The prevalence of these mobile devices is driven in part by the many functions that are now enabled on such devices. Demand for such functions increases processing capability requirements and generates a need for more powerful batteries. Within the limited space of the housing of the mobile communication device, batteries compete with the processing circuitry. The competition for space within the housing and other factors contribute to a continued miniaturization of components and power consumption within the circuitry.

Concurrent with the miniaturization pressures, there are pressures to reduce voltage levels within the mobile communication devices. Reduced voltage levels extend battery life and reduce heat generation within the mobile device. While there is pressure to reduce voltage levels, the presence of increasingly large memory blocks with a need for correspondingly larger voltage levels provides an opposing pressure. In many instances, these memory blocks are made from random access memory (RAM) and more particularly are made from static RAM (SRAM) having operating voltages on bit lines and word lines to perform row and column accesses for read and write commands to and from the memory bitcell. It is the length of the bit lines and word lines that negatively impacts the required voltage levels within the memory cell array. That is, in large arrays, the length of the bit line or word line may introduce enough capacitive or resistive qualities to diminish the voltage at distant bitcells to such a level that the desired low operating voltages are insufficient to operate the transistors at the distant bitcell.

### SUMMARY OF THE DISCLOSURE

Embodiments disclosed in the detailed description include a monolithic three dimensional (3D) memory cell array architecture with bitcell and logic partitioning. A 3D integrated circuit (IC) (3DIC) is proposed which folds or otherwise stacks elements of the memory cells into different tiers within the 3DIC. In an exemplary embodiment, the 3DIC is a monolithic 3DIC with monolithic intertier vias (MIV) coupling elements in different tiers. In an exemplary embodiment, the bitcell is arranged in a “butterfly” arrangement—so called because the bitcells are the ‘wings’ on either side of the control logic ‘thorax.’ Each tier of the 3DIC has memory cells as well as access logic including global block control logic therein. By positioning the access logic and global block control logic in each tier with the memory cells, the length of the bit lines and word lines for each memory cell are shortened, allowing for reduced supply voltages as well as generally reducing the overall footprint of the memory device.

In this regard in one embodiment, a 3D random access memory (RAM) is provided. The 3D RAM comprises a first 3DIC tier. The first 3DIC tier comprises a first RAM data bank disposed in the first 3DIC tier. The first 3DIC tier also comprises a second RAM data bank disposed in the first 3DIC tier. The first 3DIC tier also comprises a first RAM access logic comprising a first global block control logic disposed between the first RAM data bank disposed in the first 3DIC tier and the second RAM data bank disposed in the first 3DIC tier, the RAM access logic configured to control data access to the first RAM data bank disposed in the first 3DIC tier and the second RAM data bank disposed in the first 3DIC tier. The 3D RAM also comprises a second 3DIC tier. The second 3DIC tier comprises a first RAM data bank disposed in the second 3DIC tier. The second 3DIC tier also comprises a second RAM data bank disposed in the second 3DIC tier. The second 3DIC tier also comprises a second RAM access logic comprising a second global block control logic disposed between the first RAM data bank disposed in the second 3DIC tier and the second RAM data bank disposed in the second 3DIC tier, the second RAM access logic configured to control data access to the first RAM data bank disposed in the second 3DIC tier and the second RAM data bank disposed in the second 3DIC tier.

In another embodiment, a 3D RAM is disclosed. The 3D RAM comprises a first 3DIC tier. The first 3DIC tier comprises a first memory means disposed in the first 3DIC tier. The first 3DIC tier also comprises a second memory means disposed in the first 3DIC tier. The first 3DIC tier also comprises a first RAM access logic comprising a first global block control logic disposed between the first memory means disposed in the first 3DIC tier and the second memory means disposed in the first 3DIC tier, the RAM access logic configured to control data access to the first memory means disposed in the first 3DIC tier and the second memory means disposed in the first 3DIC tier. The 3D RAM also comprises a second 3DIC tier. The second 3DIC tier comprises a first memory means disposed in the second 3DIC tier. The second 3DIC tier also comprises a second memory means disposed in the second 3DIC tier. The second 3DIC tier also comprises a second RAM access logic comprising a second global block control logic disposed between the first memory means disposed in the second 3DIC tier and the second memory means disposed in the second 3DIC tier, the second RAM access logic configured to control data access to the first memory means disposed in the second 3DIC tier and the second memory means disposed in the second 3DIC tier.

### BRIEF DESCRIPTION OF THE FIGURES

FIG. 1 is a schematic diagram of a conventional memory cell;

FIG. 2 is a schematic diagram of a conventional memory cell array including memory cells such as those of FIG. 1;

FIG. 3 is a schematic diagram of a conventional memory cell array with control logic associated therewith;

FIG. 4 is a block diagram of an exemplary memory cell array according to a two-dimensional butterfly embodiment;

FIG. 5 is a simplified perspective diagram of an exemplary memory cell array according to a three-dimensional butterfly embodiment; and

FIG. 6 is a block diagram of an exemplary processor-based system that can include the memory cell array of FIG. 4 or 5.

### DETAILED DESCRIPTION

With reference now to the drawing figures, several exemplary embodiments of the present disclosure are described. The word “exemplary” is used herein to mean “serving as an example, instance, or illustration.” Any embodiment described herein as “exemplary” is not necessarily to be construed as preferred or advantageous over other embodiments.

Embodiments disclosed in the detailed description include a monolithic three dimensional (3D) memory cell array architecture with bitcell and logic partitioning. A 3D integrated circuit (IC) (3DIC) is proposed which folds or otherwise stacks elements of the memory cells into different tiers within the 3DIC. In an exemplary embodiment, the 3DIC is a monolithic 3DIC with monolithic intertier vias (MIV) coupling elements in different tiers. In an exemplary embodiment, the bitcell is arranged in a “butterfly” arrangement—so called because the bitcells are the ‘wings’ on either side of the control logic ‘thorax.’ Each tier of the 3DIC has memory cells as well as access logic including global block control logic therein. By positioning the access logic and global block control logic in each tier with the memory cells, the length of the bit lines and word lines for each memory cell are shortened, allowing for reduced supply voltages as well as generally reducing the overall footprint of the memory device.

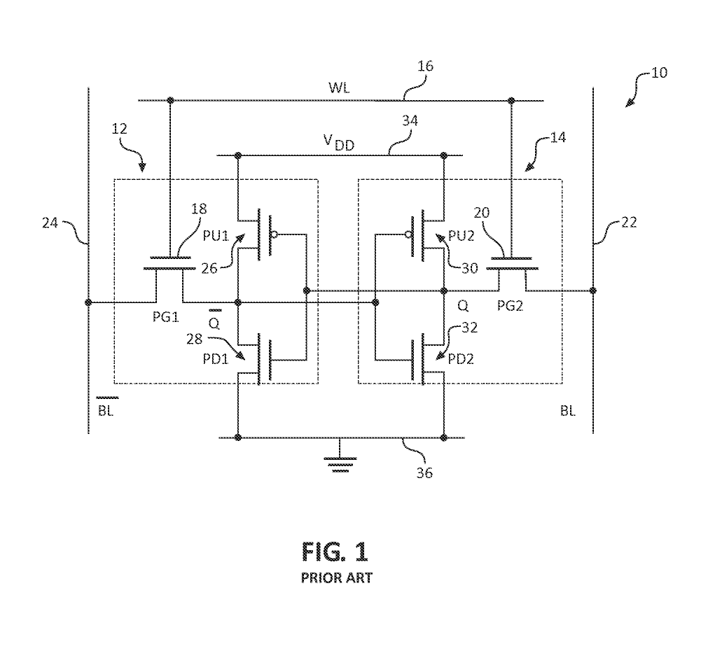

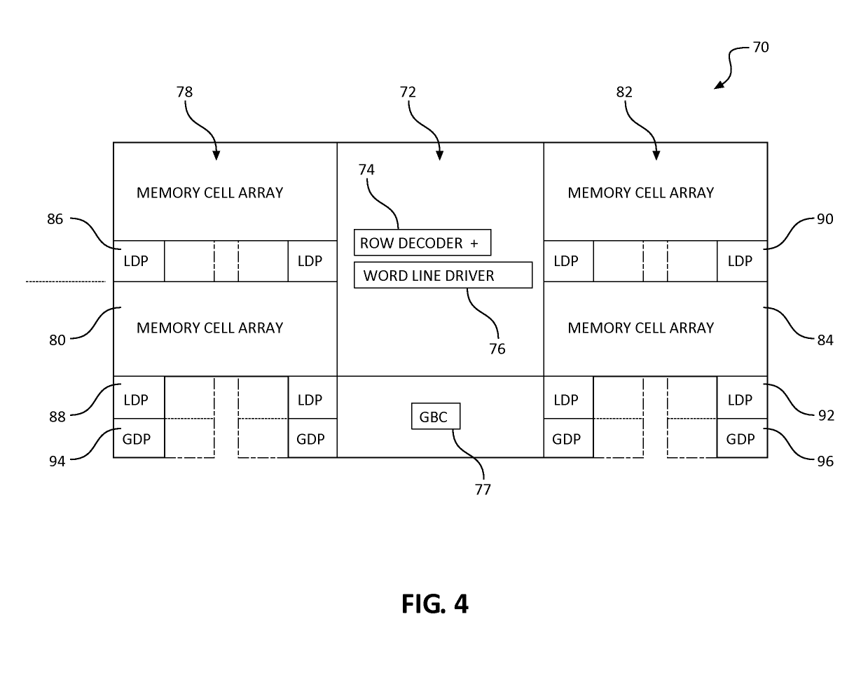

Before addressing embodiments of the present disclosure, a brief overview of a conventional memory cell array is provided with reference to FIGS. 1-3. The discussion of embodiments of the present disclosure begins below with reference to FIG. 4.

In this regard, FIG. 1 illustrates a memory cell 10 and in particular a six transistor (6T) static random access memory (RAM) (SRAM) bitcell. The memory cell 10 has a first inverter 12 and a second inverter 14. A word line (WL) 16 couples to both inverters 12, 14. In particular, the word line 16 couples to the first inverter 12 through a gate of a first pass gate (PG) transistor 18 (PG1) and couples to the second inverter 14 through a gate of a second PG transistor 20 (PG2). A bit line (BL) 22 couples to a drain of the second PG transistor 20. A bit line bar ( B̅L̅) 24 couples to a source of the first PG transistor 18.

With continued reference to FIG. 1, the first inverter 12 includes a first pull up (PU) transistor 26 (PU1) and a first pull down (PD) transistor 28 (PD1). The second inverter 14 includes a second PU transistor 30 (PU2) and a second PD transistor 32 (PD2). A voltage source (V_{DD}) 34 couples to the first and second PU transistors 26, 30. The PD transistors 28, 32 are coupled to ground 36.

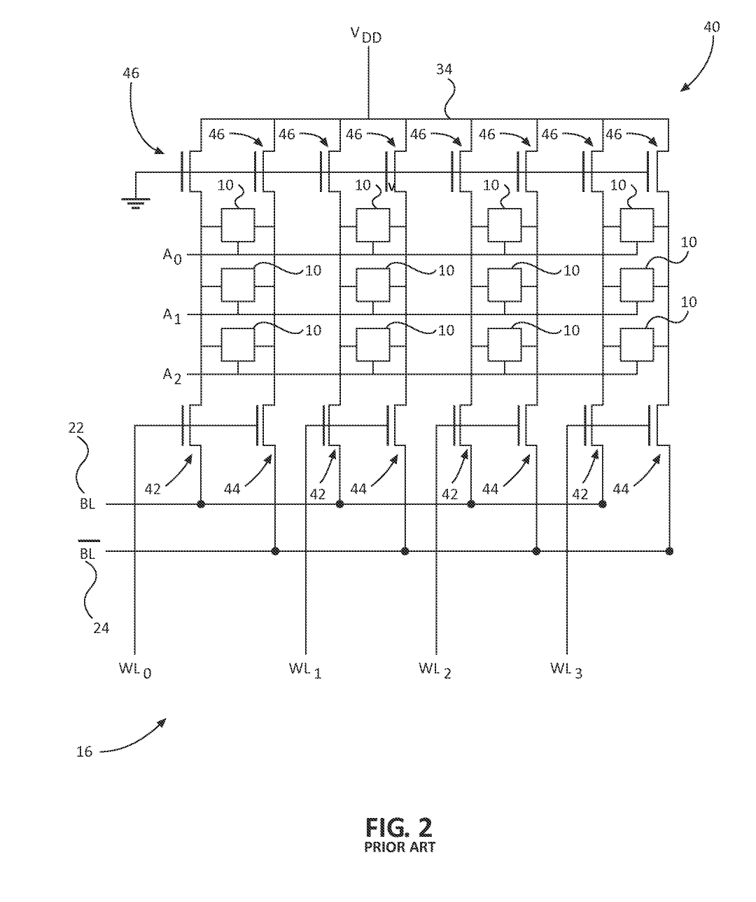

Memory cells 10 are well understood in the industry and are frequently assembled into an array of cells such memory cell array 40 illustrated in FIG. 2. In particular, memory cell array 40 is a three by four memory cell array although other arrays are also known (e.g., eight by one hundred twenty-eight, sixty-four by sixty-four, etc.). The bit line 22 and bit line bar 24 are coupled to the memory cells 10 through sense transistors 42, 44 respectively. The voltage source 34 may likewise be coupled to the memory cells through transistors 46. Likewise, the word lines 16 may be coupled to the memory cells 10 through the transistors 42, 44.

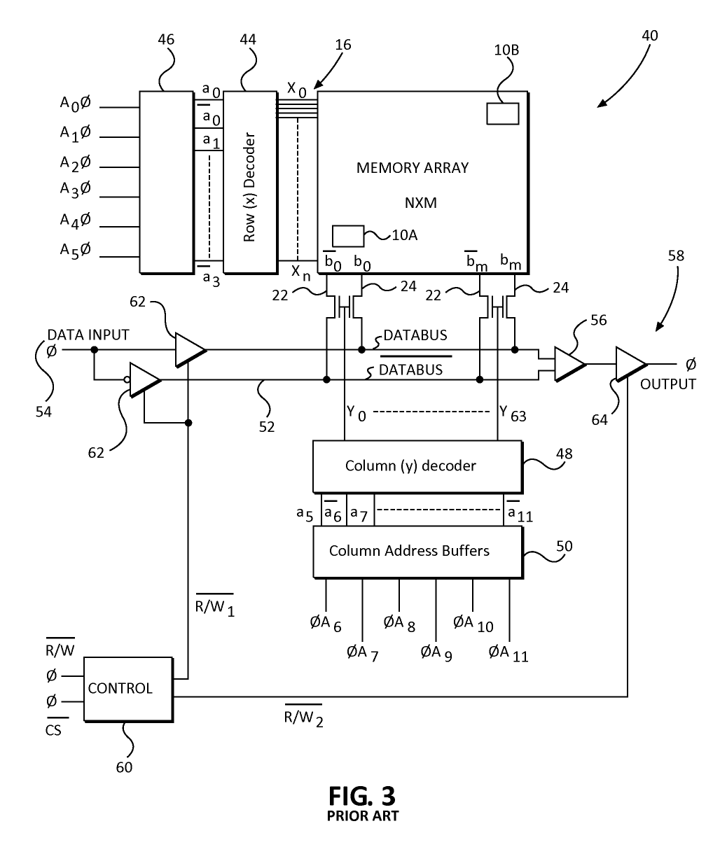

The memory cell array 40 is also well understood in the industry as are the control logic elements that are conventionally associated with such memory cell arrays. Such control logic elements are illustrated in association with memory cell array 40 in FIG. 3. In particular, the memory cell array 40 is coupled to a row decoder 44 by word lines 16. The row decoder 44 may be coupled to row address buffers 46. The memory cell 40 is further coupled to a column decoder 48 by bit lines 22 and bit lines bar 24. The column decoder 48 may be coupled to column address buffers 50. A databus 52 having a databus line and a databus bar line (databus) couples data input 54 to the bit lines 22, 24. The databus 52 may further couple to a sense amplifier 56 which provides a signal to an output 58. A control logic 60 may control input buffers 62 and output buffer 64.

As bit lines 22, bit lines bar 24, and word lines 16 get longer to reach the distant memory cells 10 within the memory cell array 40 (e.g., memory cell 10A, in the lower left corner has relatively short lines 16, 22, 24 compared to memory cell 10B in the upper right corner), the physical properties of the lines 16, 22, 24 introduce capacitive and resistive losses, which require the voltage applied to those lines to be elevated above the hypothetical minimum voltage required. Such elevated voltages decrease battery life, generate waste heat, and are otherwise considered undesirable.

One solution to shorten the length of the bit lines 22, bit lines bar 24, and word lines 16 is to arrange the memory cell arrays in a so-called “butterfly” configuration. That is, the memory cell arrays are positioned on either side of the control logic elements. Continuing the metaphor, the control logic becomes the “thorax” of the butterfly and the memory cell arrays are the “wings.” A simplified block diagram of an exemplary embodiment of a two dimensional (2D) butterfly RAM 70 is illustrated in FIG. 4. The butterfly RAM 70 has a core 72 having a row decoder 74 and word line driver 76 as well as a global block control (GBC) unit 77. The GBC has all the processing logic to select the particular read/write multiplexers for the input and output of the memory. The core 72 may be adjacent to multiple memory cell arrays 78, 80, 82, 84. Each memory cell array 78, 80, 82, 84 has a local data path (LDP) 86, 88, 90, 92 respectively. The LDPs 86, 88, 90, 92 may include any sense amplifiers (e.g., sense amplifier 56) and any multiplexer (mux) as well as the actual drivers for controlling the memory cells. Each side of the core 72 may have a global data path (GDP) 94, 96, which includes the inputs and outputs for the butterfly RAM 70. However, only one GDP 94, 96 is needed per side.

By placing the LDPs 86, 88, 90, 92 in this fashion, the length of the bit lines 22, bit lines bar 24, and word lines 16 (not illustrated in FIG. 4) are shortened. Shortening these lines 22, 24, 16 reduces the voltage levels needed to operate the RAM 70 compared to a conventional memory cell array 40. Additionally, by having shorter lines, clock skew may be minimized

While the advantages of a 2D butterfly RAM 70 are impressive, the advent of 3DIC technology allows for even greater improvements in reducing line lengths, improving miniaturization by reducing the footprint of the memory, and customizing the memory device according to the needs of the circuit designer. The use of 3DIC technology allows the “wings” of the butterfly RAM 70 to be folded one atop the other such that the overall footprint is halved (or more) while maintaining the same memory storage capabilities. Additionally, different manufacturing techniques may be used between the different tiers of the 3DIC to allow for different flavors of memory to be provided on different tiers.

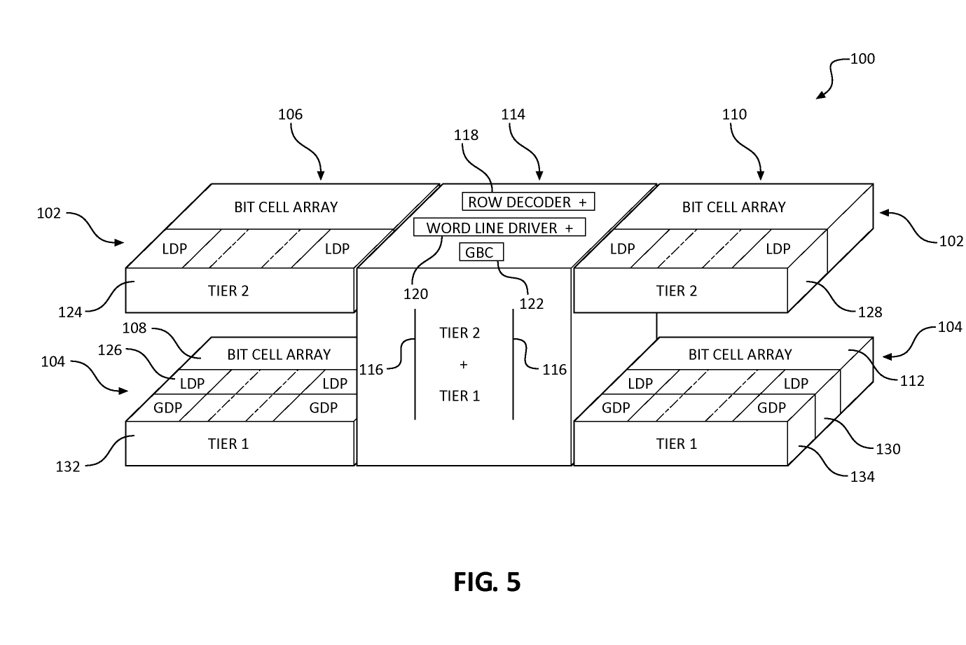

In this regard, FIG. 5 illustrates a 3D butterfly RAM 100 having a first tier 102 and a second tier 104. It should be appreciated that more tiers may be provided (not illustrated). The spacing between tiers 102, 104 is exaggerated somewhat so as to show how the RAM data banks (also referred to as bit cell arrays) 106, 108, 110, 112 extend to either side of the core 114. Also illustrated are stylized representations of MIV 116 extending from the first tier 102 to the second tier 104 within the core 114. While not illustrated, additional MIV may exist between the tiers 102, 104 outside the core 114. As with the 2D butterfly RAM 70, the row decoder 118, word line driver 120 and GBC 122 are positioned in the core 114. Each RAM data bank 106, 108, 110, 112 has a respective LDP 124, 126, 128, 130. Additionally, the GDP 132, 134 are positioned in the second tier 104, which is, as illustrated, on the bottom of the 3D butterfly RAM 100. In an alternate embodiment, the GDP 132, 134 may be in the first tier 102 and thus be on the top of the 3D butterfly RAM 100.

In practice, by putting the access logic of the row decoder 118 and the word line driver 120 as well as the GBC 122 in the core 114, along with the folded nature of the RAM data banks, shorter wire lengths are achieved for the word-lines 16, bit lines 22 and bit lines bar 24 (not illustrated in FIG. 5). Shorter wire lengths increase memory read/write access times and saves dynamic power through reduced back-end-of-line capacitance. The folding of the RAM data banks can also result in smaller die areas resulting in increased density and smaller die and packaging costs. While described as generic RAM, both dynamic RAM (DRAM) and SRAM may benefit from the present disclosure.

The monolithic 3D RAM array architecture with bitcell and logic partitioning according to embodiments disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

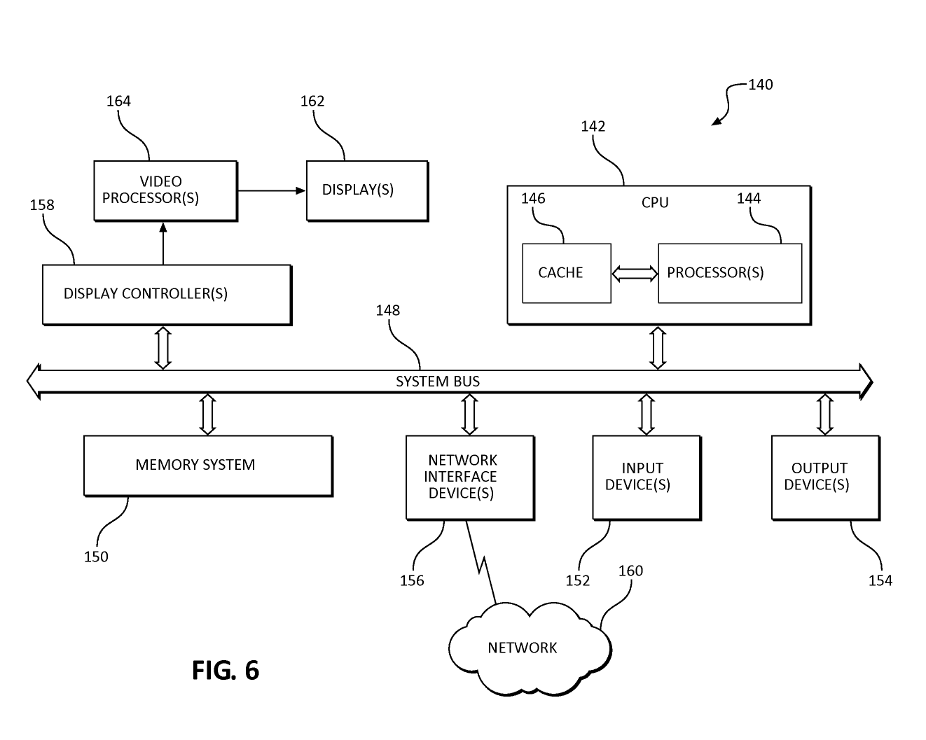

In this regard, FIG. 6 illustrates an example of a processor-based system 140 that can employ the 3D butterfly RAM 100 illustrated in FIG. 5. In this example, the processor-based system 140 includes one or more central processing units (CPUs) 142, each including one or more processors 144. The CPU(s) 142 may be a master device. The CPU(s) 142 may have cache memory 146 which includes one or more 3D butterfly RAM 100 coupled to the processor(s) 144 for rapid access to temporarily stored data. The CPU(s) 142 is coupled to a system bus 148 and can intercouple master devices and slave devices included in the processor-based system 140. As is well known, the CPU(s) 142 communicates with these other devices by exchanging address, control, and data information over the system bus 148. For example, the CPU(s) 142 can communicate bus transaction requests to the memory system 150 that may include one or more 3D butterfly RAM 100. Although not illustrated in FIG. 6, multiple system buses 148 could be provided, wherein each system bus 148 constitutes a different fabric.

Other master and slave devices can be connected to the system bus 148. As illustrated in FIG. 6, these devices can include the memory system 150, one or more input devices 152, one or more output devices 154, one or more network interface devices 156, and one or more display controllers 158, as examples. The input device(s) 152 can include any type of input device, including but not limited to input keys, switches, voice processors, etc. The output device(s) 154 can include any type of output device, including but not limited to audio, video, other visual indicators, etc. The network interface device(s) 156 can be any devices configured to allow exchange of data to and from a network 160. The network 160 can be any type of network, including but not limited to a wired or wireless network, private or public network, a local area network (LAN), a wide local area network (WLAN), and the Internet. The network interface device(s) 156 can be configured to support any type of communication protocol desired.

The CPU(s) 142 may also be configured to access the display controller(s) 158 over the system bus 148 to control information sent to one or more displays 162. The display controller(s) 158 sends information to the display(s) 162 to be displayed via one or more video processors 164, which process the information to be displayed into a format suitable for the display(s) 162. The display(s) 162 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the embodiments disclosed herein may be implemented as electronic hardware, instructions stored in memory or in another computer-readable medium and executed by a processor or other processing device, or combinations of both. The arbiters, master devices, and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the embodiments disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The embodiments disclosed herein may be embodied in hardware and in instructions that are stored in hardware, and may reside, for example, in RAM, flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary embodiments herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary embodiments may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A three dimensional (3D) random access memory (RAM), comprising:
a first 3D integrated circuit (IC) (3DIC) tier, comprising:
a first RAM data bank disposed in the first 3DIC tier;
a second RAM data bank disposed in the first 3DIC tier;
a first RAM access logic comprising a first global block control logic disposed between the first RAM data bank disposed in the first 3DIC tier and the second RAM data bank disposed in the first 3DIC tier, the RAM access logic configured to control data access to the first RAM data bank disposed in the first 3DIC tier and the second RAM data bank disposed in the first 3DIC tier;
a second 3DIC tier, comprising:
a first RAM data bank disposed in the second 3DIC tier;
a second RAM data bank disposed in the second 3DIC tier;
a second RAM access logic comprising a second global block control logic disposed between the first RAM data bank disposed in the second 3DIC tier and the second RAM data bank disposed in the second 3DIC tier, the second RAM access logic configured to control data access to the first RAM data bank disposed in the second 3DIC tier and the second RAM data bank disposed in the second 3DIC tier.

2. The 3D RAM of claim 1, wherein the first RAM data bank in the first tier is comprised of at least one static RAM (SRAM) data bank.

3. The 3D RAM of claim 1, wherein the first RAM data bank in the first tier is comprised of at least one dynamic RAM (DRAM) data bank.

4. The 3D RAM of claim 1 disposed in a monolithic 3DIC.

5. The 3D RAM of claim 1, further comprising at least one additional 3DIC tier with corresponding RAM data banks disposed therein.

6. The 3D RAM of claim 1, further comprising a global data path configured to provide input and output for the 3D RAM.

7. The 3D RAM of claim 6, wherein the global data path is positioned on a top 3DIC tier of the first and second 3DIC tiers.

8. The 3D RAM of claim 6, wherein the global data path is positioned on a bottom 3DIC tier of the first and second tiers.

9. The 3D RAM of claim 1, further comprising a plurality of monolithic intertier vias (MIV) coupling the first tier to the second tier.

10. The 3D RAM of claim 1 integrated into an IC.

11. The 3D RAM of claim 1 integrated into a device selected from the group consisting of a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

12. A three dimensional (3D) random access memory (RAM), comprising:
a first 3D integrated circuit (IC) (3DIC) tier, comprising:
a first memory means disposed in the first 3DIC tier;
a second memory means disposed in the first 3DIC tier;
a first RAM access logic comprising a first global block control logic disposed between the first memory means disposed in the first 3DIC tier and the second memory means disposed in the first 3DIC tier, the RAM access logic configured to control data access to the first memory means disposed in the first 3DIC tier and the second memory means disposed in the first 3DIC tier;
a second 3DIC tier, comprising:
a first memory means disposed in the second 3DIC tier;
a second memory means disposed in the second 3DIC tier;
a second RAM access logic comprising a second global block control logic disposed between the first memory means disposed in the second 3DIC tier and the second memory means disposed in the second 3DIC tier, the second RAM access logic configured to control data access to the first memory means disposed in the second 3DIC tier and the second memory means disposed in the second 3DIC tier.

13. The 3D RAM of claim 12, wherein the first memory means disposed in the first 3DIC tier comprises a RAM data bank.

14. The 3D RAM of claim 12 disposed within a monolithic IC.

15. The 3D RAM of claim 14, further comprising a plurality of monolithic intertier vias (MIV) coupling the first tier to the second tier.

16. The 3D RAM of claim 13, wherein the RAM data bank comprises at least one static RAM (SRAM) data bank.

17. The 3D RAM of claim 13, wherein the RAM data bank comprises at least one dynamic RAM (DRAM) data bank.

18. The 3D RAM of claim 12, further comprising at least one additional 3DIC tier with corresponding RAM data banks disposed therein.

19. The 3D RAM of claim 12, further comprising a global data path configured to provide input and output for the 3D RAM.

20. The 3D RAM of claim 19, wherein the global data path is positioned on a top 3DIC tier of the first and second 3DIC tiers.
